(19) United States
(12) Patent Application Publication
(10) Pub. No.: US 2013/0182195 A1
(43) Pub. Date: Jul. 18, 2013

(54) TELEVISION AND ELECTRONIC APPARATUS

(71) Applicant: KABUSHIKI KAISHA TOSHIBA, Tokyo (JP)

(72) Inventor: Yuji Nakajima, Nishitama-gun (JP)

(73) Assignee: KABUSHIKI KAISHA TOSHIBA, Tokyo (JP)

(21) Appl. No.: 13/679,796

(22) Filed: Nov. 16, 2012

(30) Foreign Application Priority Data
Jan. 13, 2012 (JP) 2012-005264

(51) Int. Cl. H04N 5/64; H05K 5/00

(52) U.S. Cl. CPC H04N 5/64; H05K 5/0091
USPC 348/836; 361/747

(57) ABSTRACT

According to one embodiment, an electronic apparatus includes a housing including a lock, a module configured to attach to the housing and to engage the lock, a link configured to associate with the lock, and a support configured to be moved to the module by link and to contact the module when the lock is locked.

### CROSS-REFERENCE TO RELATED APPLICATIONS

This application is based upon and claims the benefit of priority from prior Japanese Patent Application No. 2012-005264, filed Jan. 13, 2012, the entire contents of which are incorporated herein by reference.

### FIELD

Embodiments described herein relate generally to electronic apparatuses including televisions.

### BACKGROUND

An electronic apparatus has been proposed which includes a module attached to a housing.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view of a television according to a first embodiment;

FIG. 2 is an exemplary cross-sectional view of the television illustrated in FIG. 1;

FIG. 3 is an exemplary rear view of the television illustrated in FIG. 1;

FIG. 4 is an exemplary perspective view of an electronic apparatus according to a second embodiment;

FIG. 5 is an exemplary plan view of the internal structure of the electronic apparatus illustrated in FIG. 4;

FIG. 6 is an exemplary perspective view of a portion of a first housing illustrated in FIG. 4;

FIG. 7 is an exemplary perspective view of a battery illustrated in FIG. 4;

FIG. 8 is an exemplary bottom view of the battery illustrated in FIG. 4;

FIG. 9 is an exemplary perspective view of a first support illustrated in FIG. 5;

FIG. 10 is an exemplary plan view of the first support illustrated in FIG. 5;

FIG. 11 is an exemplary plan view of the first support illustrated in FIG. 5;

FIG. 12 is an exemplary perspective view of the first support illustrated in FIG. 5;

FIG. 13 is an exemplary cross-sectional view of the first support and the battery illustrated in FIG. 5;

FIG. 14 is an exemplary cross-sectional view of the first support taken along the line F14-F14 of FIG. 13;

FIG. 15 is an exemplary cross-sectional view of the first support and the battery illustrated in FIG. 5;

FIG. 16 is an exemplary cross-sectional view of the first support taken along the line F16-F16 of FIG. 15;

FIG. 17 is an exemplary plan view of a second support illustrated in FIG. 5;

FIG. 18 is an exemplary plan view of the second support illustrated in FIG. 5;

FIG. 19 is an exemplary bottom view of an electronic apparatus according to a third embodiment;

FIG. 20 is an exemplary front view of an external connection device according to a fourth embodiment; and

FIG. 21 is an exemplary bottom view of an electronic apparatus according to a fifth embodiment.

### DETAILED DESCRIPTION

Various embodiments will be described hereinafter with reference to the accompanying drawings.

In general, according to one embodiment, an electronic apparatus comprises a housing comprising a lock, a module configured to attach to the housing and to engage the lock, a link configured to associate with the lock, and a support configured to be moved to the module by link and to contact the module when the lock is locked.

Hereinafter, embodiments will be described with reference to the drawings.

### First Embodiment

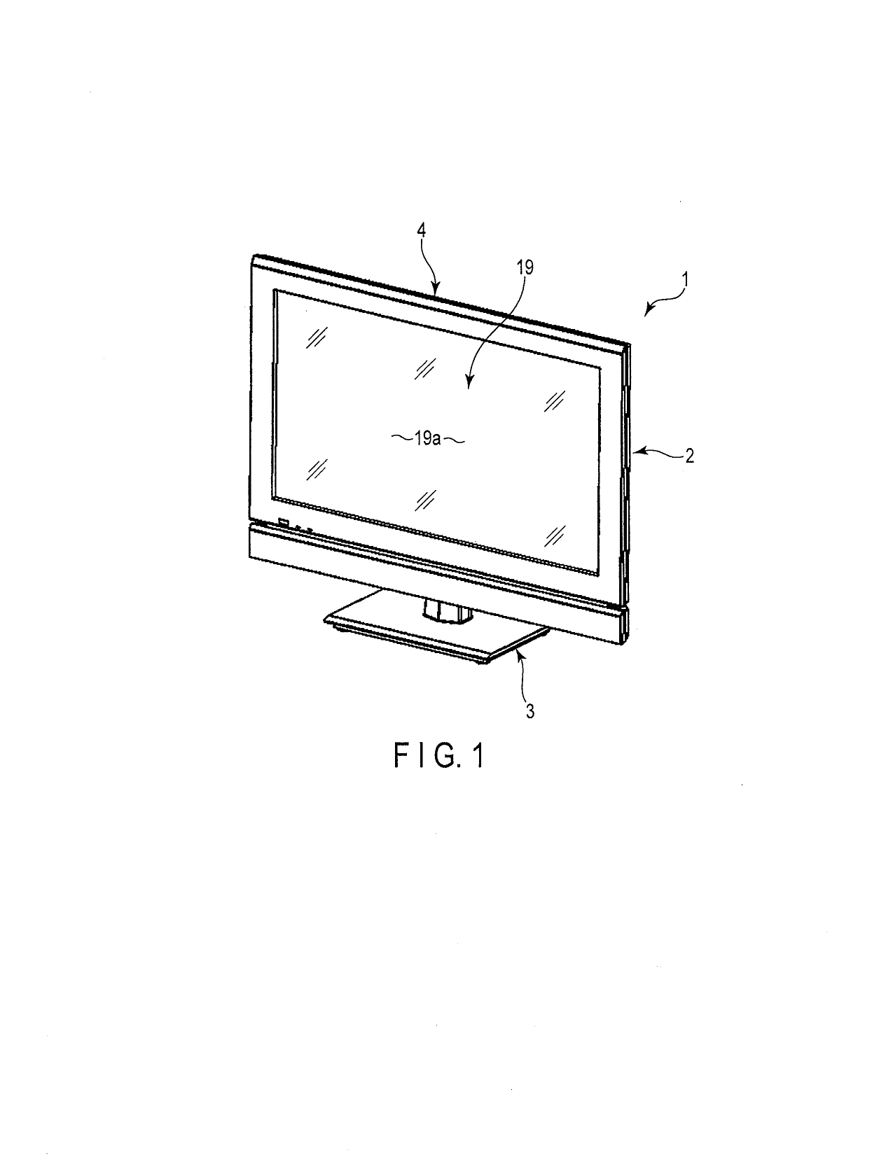

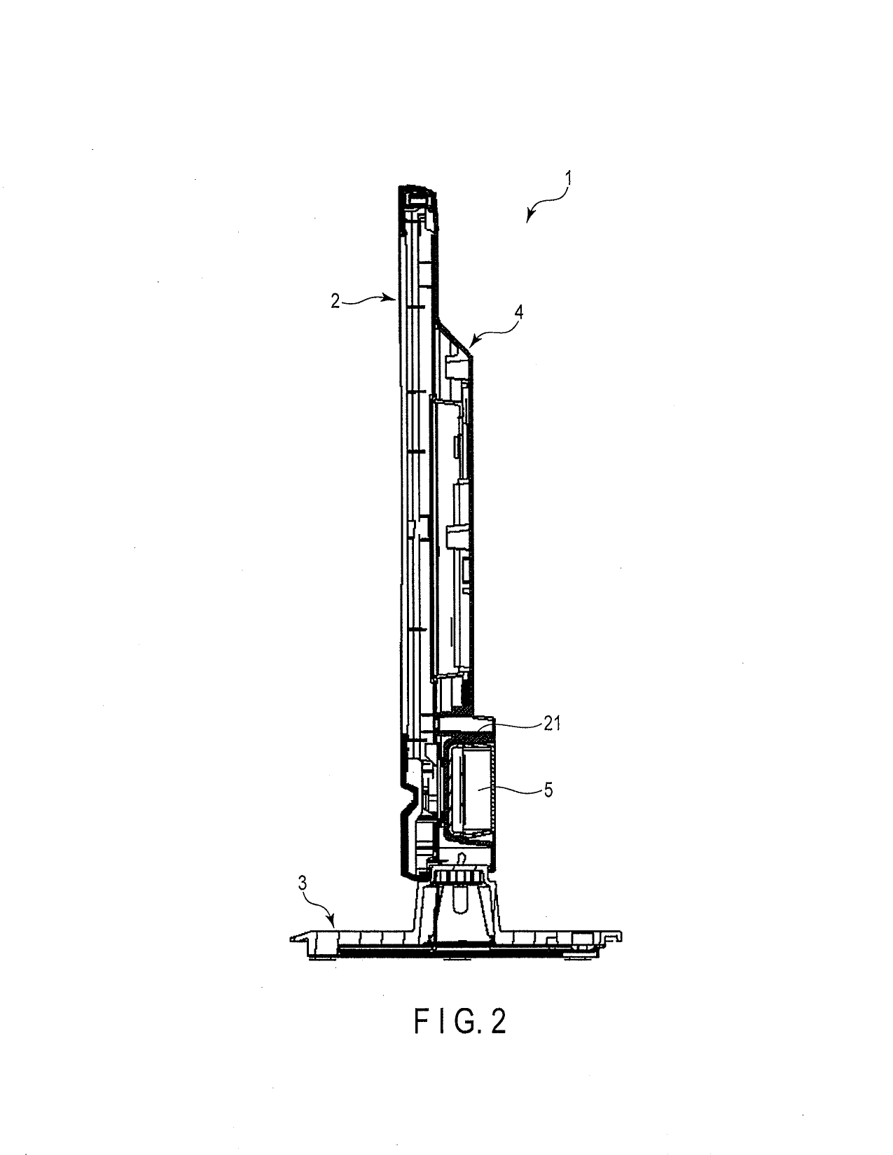

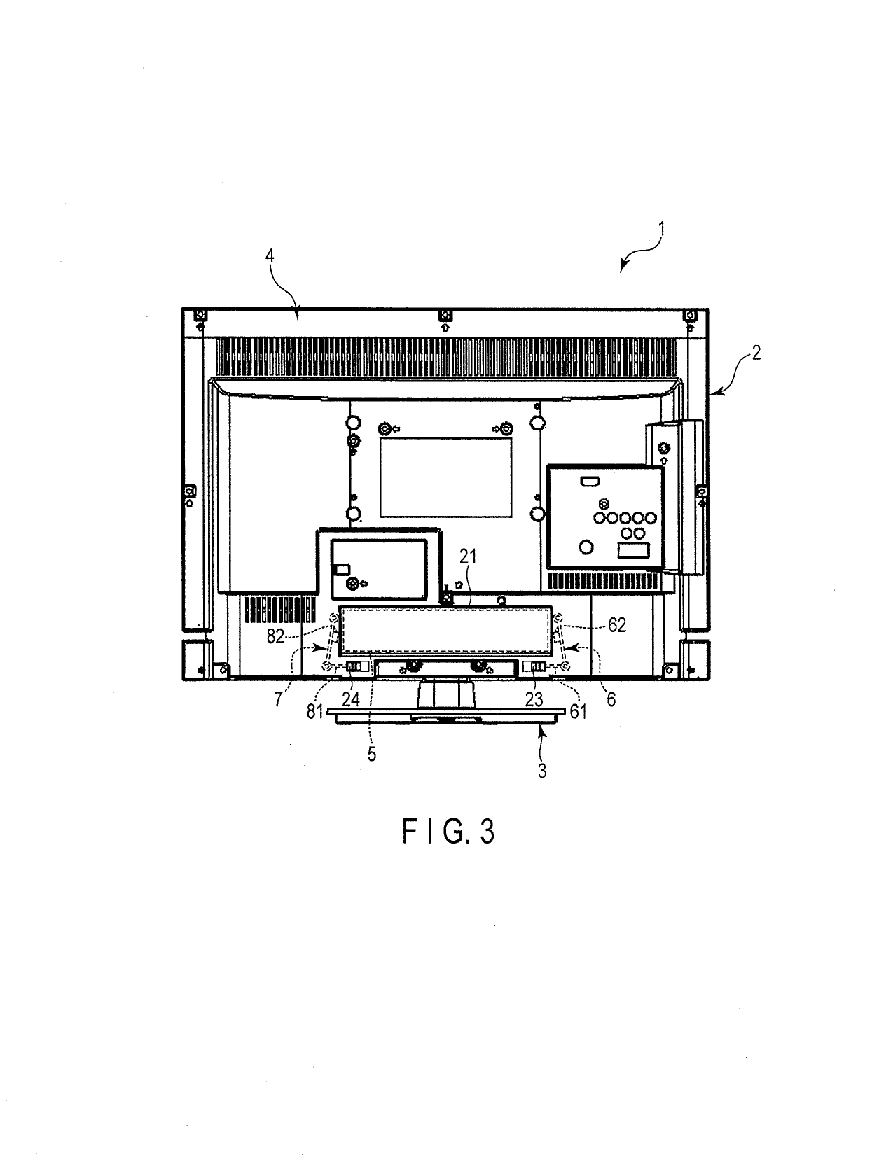

FIGS. 1 to 3 illustrate a television 1 according to a first embodiment. The television 1 is an example of an “electronic apparatus”. The television 1 includes a display unit 2 and a stand 3 that supports the display unit 2. The display unit 2 includes a housing 4 and a battery 5 that is removably attached to the housing 4. The battery 5 is an example of a “module”. The television 1 includes a first pressing portion 6 and a second pressing portion 7 that support the battery 5.

These components have substantially the same structures as those according to a second embodiment. Therefore, the second embodiment will be described in detail. Components having the same or similar functions as those in the second embodiment are denoted by the same reference numerals and the description thereof will not be repeated.

### Second Embodiment

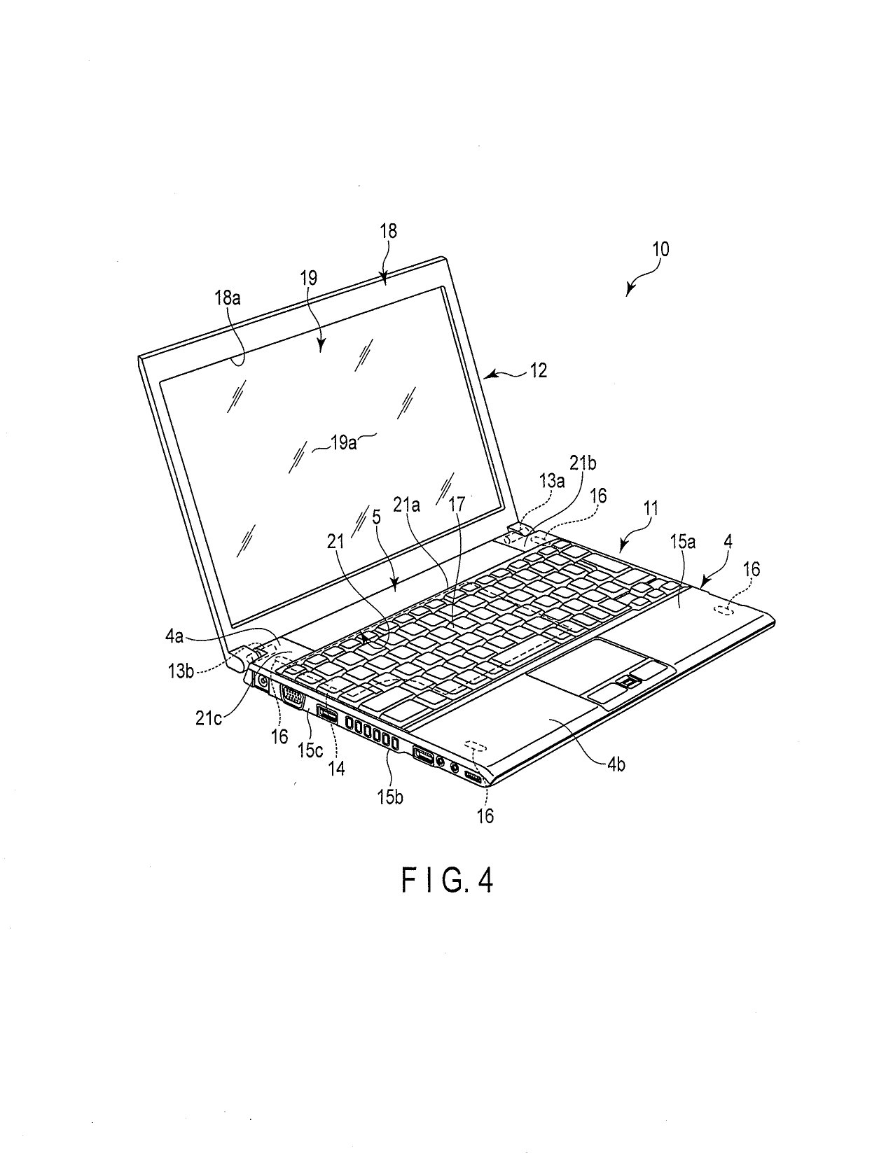

Next, an electronic apparatus 10 according to the second embodiment will be described with reference to FIGS. 4 to 18. The electronic apparatus 10 according to this embodiment is, for example, a notebook portable computer (hereinafter, referred to as a notebook PC). Electronic apparatuses to which this embodiment and the third to fifth embodiments, which will be described below, can be applied are not limited to the notebook PC. The first to fifth embodiments can be widely applied to various electronic apparatuses including televisions, mobile phones (including smart phones), and tablet terminals (slate PCs).

As illustrated in FIG. 4, the electronic apparatus 10 includes a first unit 11, a second unit 12, and hinges 13a and 13b. The first unit 11 is, for example, a main unit. The first unit 11 includes a first housing 4 and a battery 5 that is removably attached to the first housing 4. The battery 5 is an example of a “module” or a “unit”. The “module” or “unit” is not limited to the battery, but may be various members that can be removably attached to the housing 4, such as an ODD unit, a projector, and a sub-battery.

The first housing 4 includes, for example, a circuit board 14 serving as a main board. The first housing 4 includes an upper wall 15a, a lower wall 15b, and a circumferential wall 15c and has a flat box shape. In the specification, the upper, lower, left, and right sides are defined in the viewing direction of the user. The side close to the user is defined as the “front side” and the side away from the user is defined as the “rear side”.

The lower wall 15b faces a desk surface (i.e., outer surface, mounting surface, or outer mounting surface) when the electronic apparatus 10 is placed on a desk. For example, a plurality of leg portions 16 (i.e., support) that come into contact with the desk surface are provided on the lower wall 15b. The upper wall 15a is opposite to the lower wall 15b with a space therebetween and extends substantially in parallel to the lower wall 15b. The circumferential wall 15c extends in a direction crossing the lower wall 15b and connects the edge of the lower wall 15b and the edge of the upper wall 15a.

A keyboard 17 is provided on the upper wall 15a. The keyboard 17 is an example of an “input unit (i.e., input receiving unit)”. However, the input unit is not limited thereto. For example, the input unit 15 may be a touch panel (i.e., touch sensor) or other input devices.

The first housing 4 includes a first end 4a and a second end 4b. The first end 4a is, for example, the rear end and extends in the longitudinal direction (i.e., the width direction of the housing) of the first housing 4. The hinges 13a and 13b are provided at the first end 4a. The second end 4b is opposite to the first end 4a and is, for example, the front end.

The second unit 12 is, for example, a display unit. The second unit 12 includes a second housing 18 and a display device 19 (i.e., a display portion) provided in the second housing 18. The display device 19 is, for example, a liquid crystal display (LCD), but is not limited thereto. The display device 19 includes a display screen 19a. The display screen 19a is exposed to the outside through an opening 18a of the second housing 18.

The second housing 18 is rotatably connected to the first end 4a of the first housing 4 via the hinges 13a and 13b. In this way, the electronic apparatus 10 can be deformed (e.g., rotated) between a first state (i.e., first position) in which the first housing 4 and the second housing 18 overlap each other and a second state (i.e., second position) in which the second housing 18 is separated from the first housing 4. In the first state, the keyboard 17 and the display screen 19a are exposed to the outside. In the second state, the keyboard 17 and the display screen 19a are hidden from the outside.

Next, the attachment structure of the battery 5 will be described.

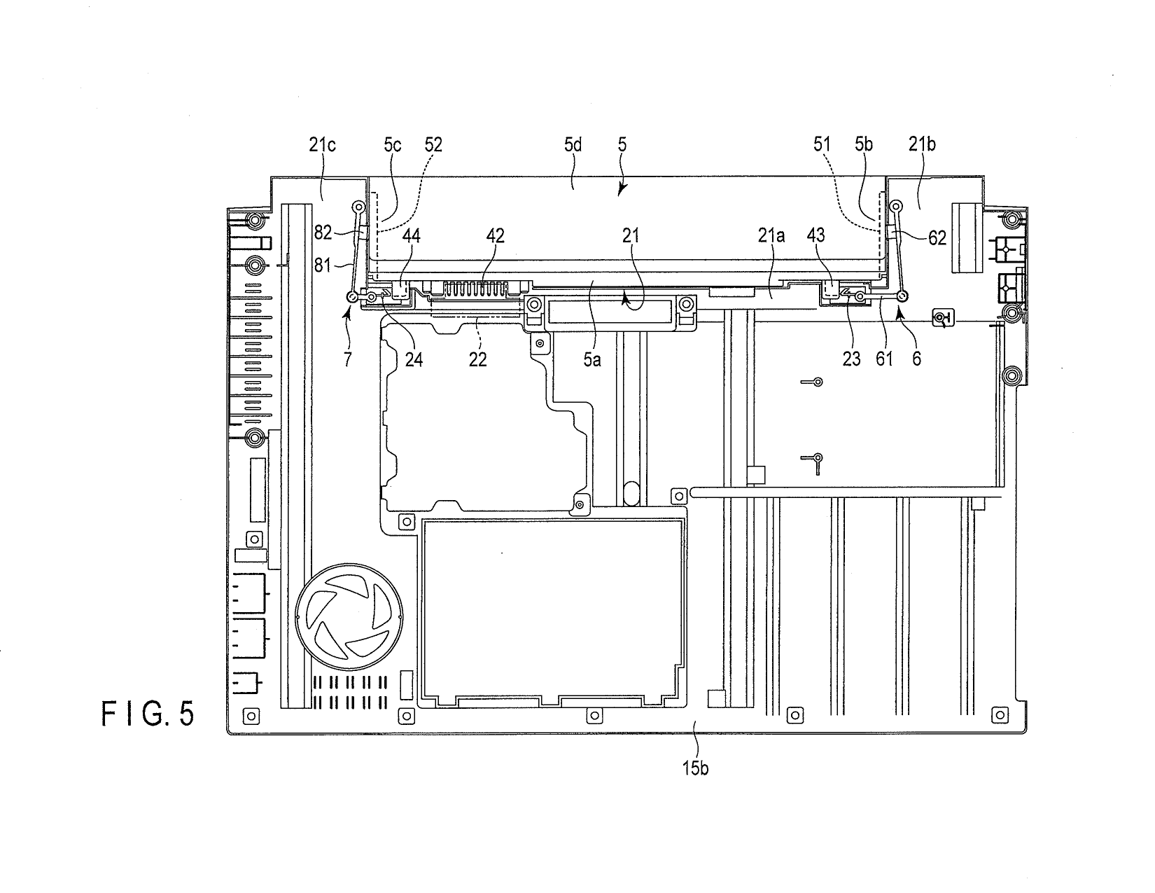

As illustrated in FIGS. 4 and 5, the battery 5 is attached to the first end 4a of the first housing 4 (hereinafter, referred to as the housing 4). A recess accommodating portion 21 to which the battery 5 is attached is provided at the first end 4a.

Specifically, as illustrated in FIG. 5, the housing 4 includes first to third portions 21a, 21b, and 21c. The first to third portions 21a, 21b, and 21c define the accommodating portion 21. The first portion 21a is provided at a position which is recessed from the rear end of the housing 4 and extends in the longitudinal direction (e.g., left-right direction) of the housing 4. The first portion 21a faces the battery 5 in a direction (e.g., insertion direction) in which the battery 5 is attached.

A first connector 22, a first lock 23, and a second lock 24 are provided in the first portion 21a. The first connector 22 is, for example, a battery connector and includes a plurality of pins to be connected to the battery 5. Each of the first lock 23 and the second lock 24 is for connecting the battery 5 to the housing 4 and is an example of a “lock portion”, a “lock lever”, a “sliding portion”, a “sliding component”, a “fixing portion”, a “support”, a “coupling portion”, a “connection portion”, a “joining portion”, a “stopper portion”, a “region”, a “portion”, or a “member”.

As illustrated in FIGS. 4 and 5, the second portion 21b and the third portion 21c are projections which are separately provided on both sides of the first portion 21a and protrude backward from the first portion 21a. The hinges 13a and 13b are provided in the second portion 21b and the third portion 21c, respectively. The accommodating portion 21 is provided between the second portion 21b and the third portion 21c and the upper, lower, and rear sides thereof are opened. That is, the battery 5 is attached between the second portion 21b and the third portion 21c and the upper, lower, and rear sides thereof are exposed.

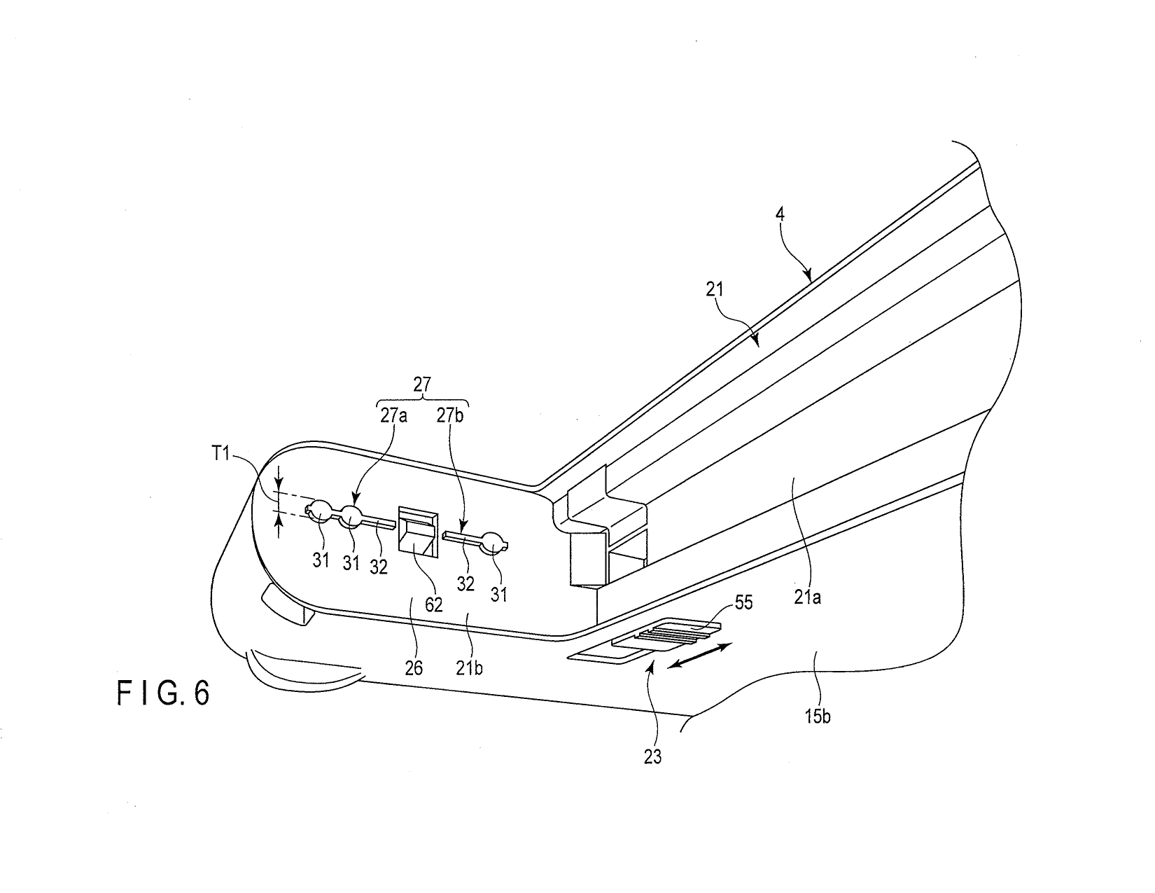

As illustrated in FIG. 6, the second portion 21b includes a wall 26 (e.g., a housing wall, an outer wall, an outer surface, or a surface), and a first guide 27. The wall 26 extends in the thickness direction of the housing 4 and faces a second end 5b (which will be described below) of the battery 5. The first guide 27 is an example of a “rail”, a “wall”, a “guide”, a “support”, a “guide portion”, a “positioning portion”, a “region”, or a “portion”. The first guide 27 is, for example, a projection that protrudes from the wall 26. The first guide 27 extends in the direction (e.g., insertion direction) in which the battery 5 is attached and guides the second end 5b of the battery 5.

As illustrated in FIG. 6, the first guide 27 includes a first portion 27a and a second portion 27b that are independently provided and are separated from each other. Each of the first portion 27a and the second portion 27b includes a thick portion 31 (i.e., wide portion) and a thin portion 32 (i.e., narrow portion). The terms “thick portion” and “thin portion” mean portions with large and small widths in the thickness direction (e.g., vertical direction) of the housing 4.

The overall thickness of the first guide 27 may be constant. In this embodiment, the thin portion 32 is provided such that the first guide 27 can come into point contact with the battery 5 and guide the battery 5. In this way, the friction between the first guide 27 and the battery 5 is reduced and the battery 5 is smoothly inserted. The thickness T1 of the first guide 27 is defined by the thick portion 31.

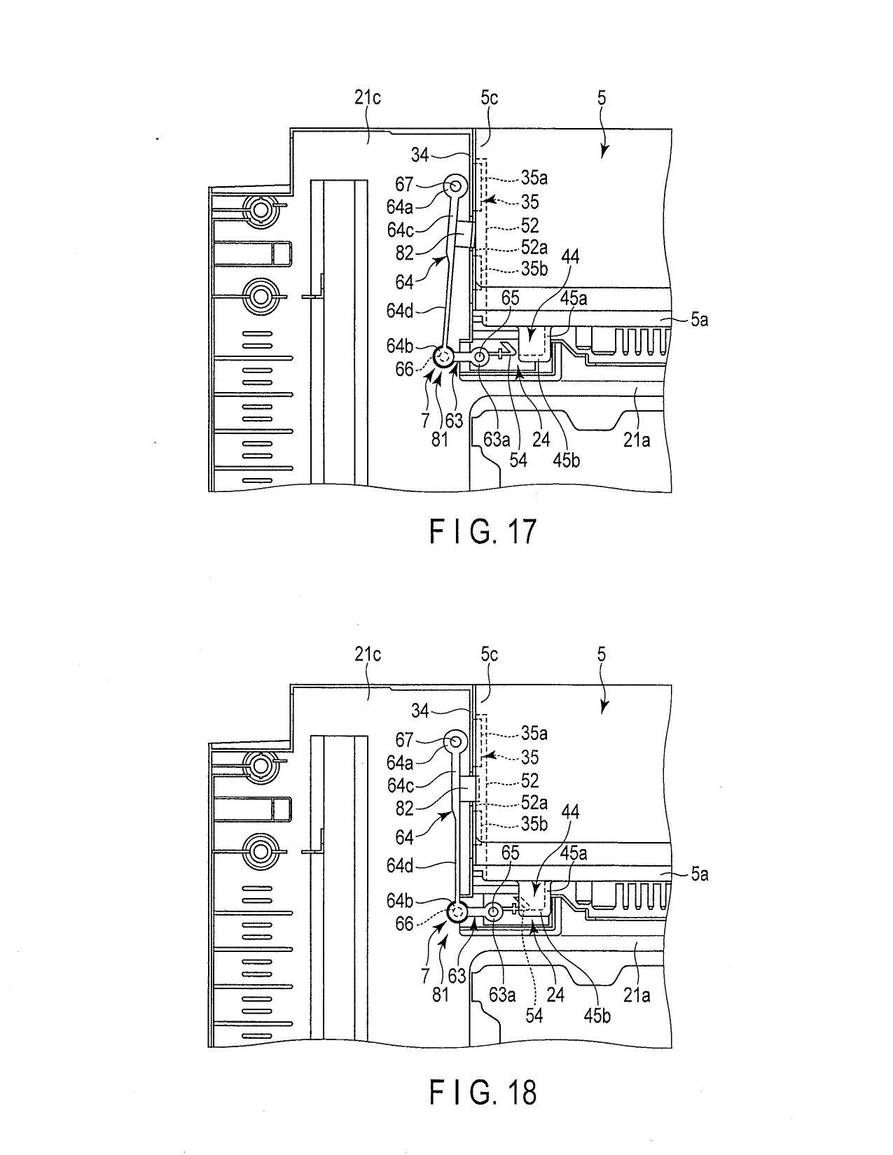

Similarly, the third portion 21c includes a wall 34 (e.g., a housing wall, an outer wall, an outer surface, or a surface) and a second guide 35 (see FIG. 17). The wall 34 extends in the thickness direction of the housing 4 and faces a third end 5c (which will be described below) of the battery 5. The second guide 35 is an example of a “rail”, a “wall”, a “guide”, a “support”, a “guide portion”, a “positioning portion”, a “region”, or a “portion”. The second guide 35 is, for example, a projection that protrudes from the wall 34. The second guide 35 extends in the direction (e.g., insertion direction) in which the battery 5 is attached and guides the third end 5c of the battery 5.

The second guide 35 includes a first portion 35a and a second portion 35b that are independently provided and are separated from each other. Similarly to the first guide 27, each of the first portion 35a and the second portion 35b includes a thick portion 31 and a thin portion 32. The overall thickness of the second guide 35 may be constant.

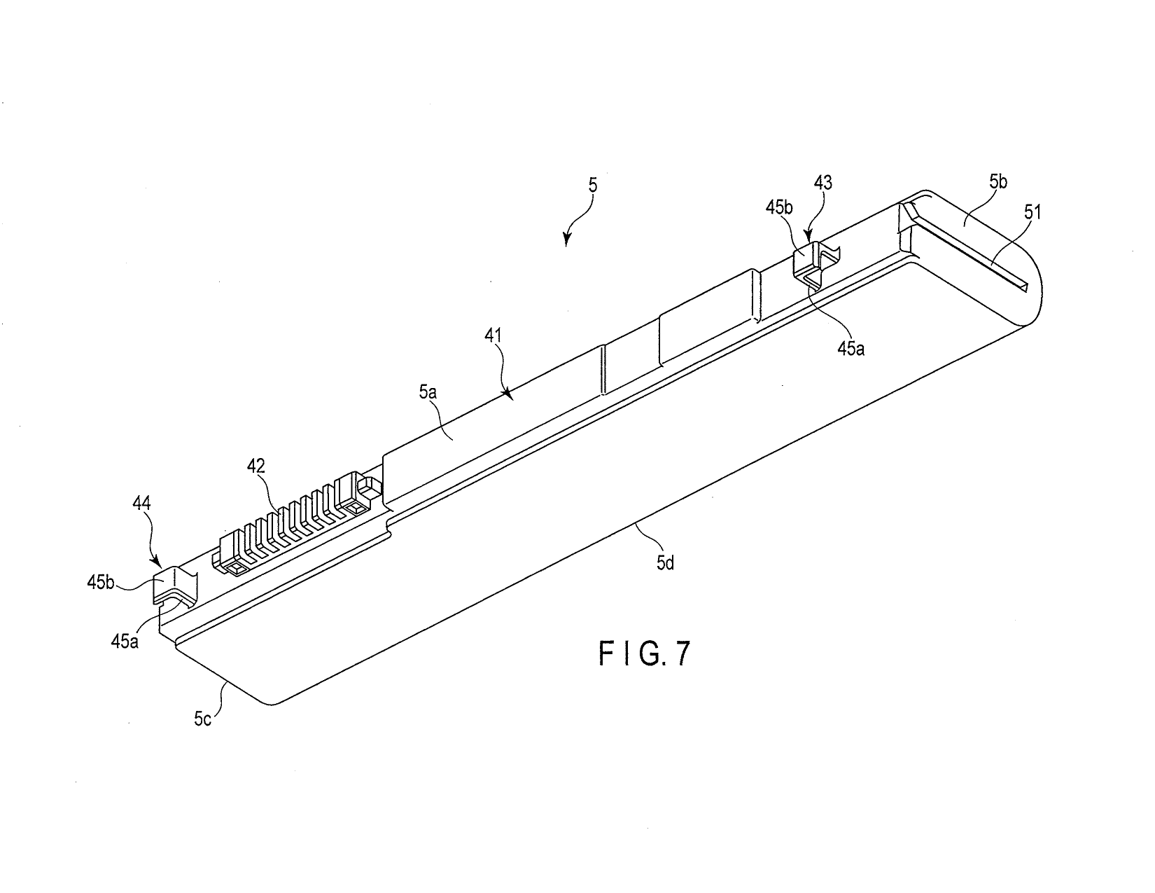

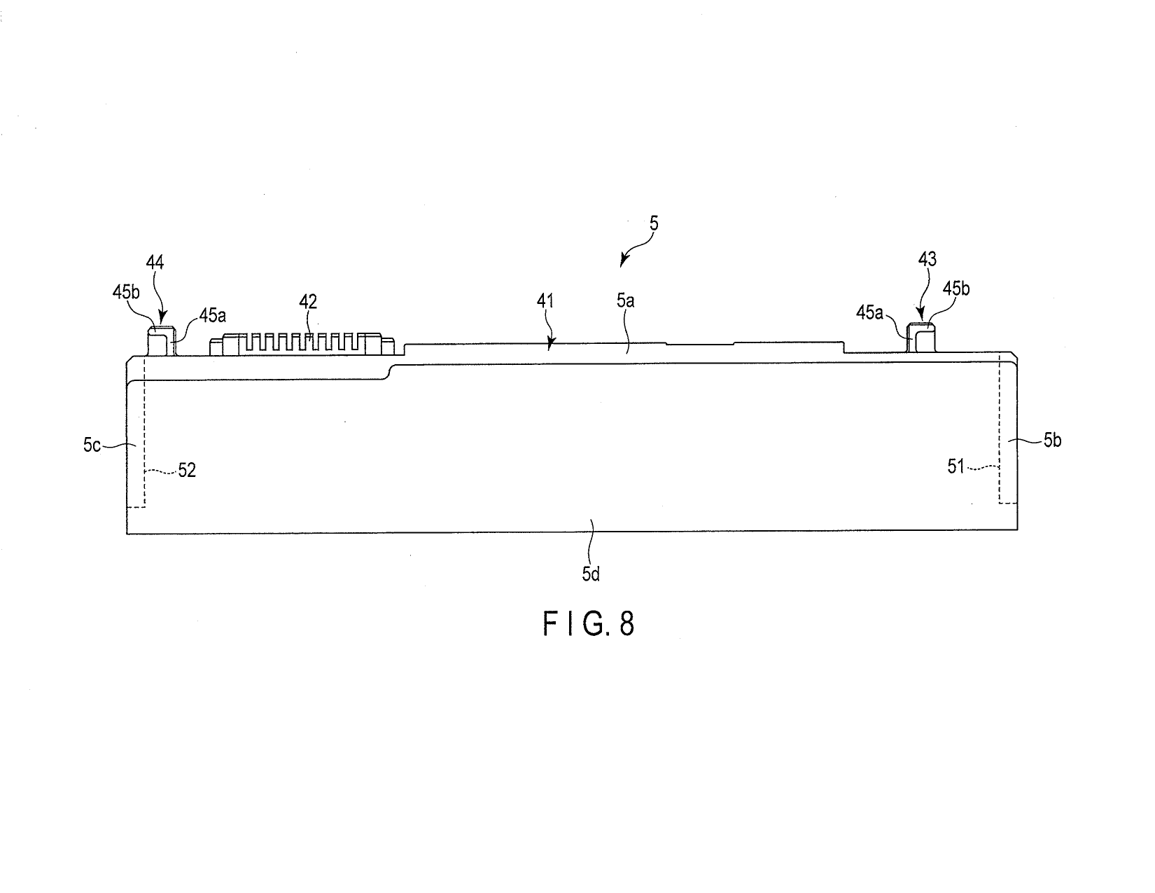

As illustrated in FIGS. 7 and 8, the battery 5 includes a long case 41 (i.e., battery case) and a plurality of cells (i.e., battery cells) provided in the case 41. The battery 5 includes a first end 5a (i.e., first surface), the second end 5b (i.e., second surface), the third end 5c (i.e., third surface), and a fourth end 5d (i.e., fourth surface). The first end 5a extends in the longitudinal direction of the battery 5. The first end 5a is, for example, the front end of the battery 5 and faces the first portion 21a of the accommodating portion 21 of the housing 4.

The second end 5b and the third end 5c are the side portions (i.e., side surfaces) of the battery 5 and extend in a direction (e.g., a direction substantially perpendicular to) crossing the first end 5a. The second end 5b faces the second portion 21b of the accommodating portion 21. The third end 5c is opposite to the second end 5b. The third end 5c faces the third portion 21c of the accommodating portion 21. The fourth end 5d is opposite to the first end 5a. The fourth end 5d is, for example, the rear end of the battery 5 and is exposed to the outside.

As illustrated in FIGS. 7 and 8, a second connector 42, a first engaging portion 43, and a second engaging portion 44 are provided at the first end 5a of the battery 5. The second connector 42 is to be connected to the first connector 22 of the housing 4 and is electrically to be connected to the first connector 22.

Each of the first engaging portion 43 and the second engaging portion 44 is an example of a “hook”, an “attachment portion”, a “fixing portion”, a “connection portion”, a “support”, a “region”, or a “portion”. Each of the first engaging portion 43 and the second engaging portion 44 includes a first portion 45a (e.g., projection) that protrudes from the case 41 and a second portion 45b (e.g., a hooking portion or a claw) that is bent from the leading end of the first portion 45a. The second portion 45b extends substantially in parallel to the first end 5a of the battery 5. A gap into which the first lock 23 or the second lock 24 is inserted is provided between the second portion 45b and the case 41.

As illustrated in FIGS. 7 and 8, a first recess 51 is provided at the second end 5b of the battery 5. The first recess 51 is an example of an “opening”, a “recessed portion”, a portion” or “region” (e.g., a sunken portion, a depressed portion, or a step portion) which is recessed from the surface of the case 41, a “receiving portion”, a “guide receiving portion”, a “groove”, or a “groove portion”. In other words, the second end 5b includes a first portion and a pair of second portions (e.g., projections) that protrude from both sides of the first portion, and the first recess 51 is provided at the second end 5b. The first recess 51 has, for example, a U-shape.

The first recess 51 is a groove that extends along the first guide 27. That is, the first recess 51 extends in the direction in which the battery 5 is attached. The first recess 51 extends to the first end 5a of the battery 5 and is opened at the first end 5a. That is, the front side of the first recess 51 is opened. In this way, the first guide 27 is inserted into the first recess 51.

The first guide 27 is fitted to the first recess 51 and the second end 5b of the battery 5 slides while being guided by the first guide 27. A gap (e.g., allowance) for sliding is formed between the first guide 27 and the first recess 51. In this way, the battery 5 is smoothly guided by the first guide 27.

Similarly, a second recess 52 is provided at the third end 5c of the battery 5. The second recess 52 is an example of an “opening”, a “recessed portion”, a portion” or “region” (e.g., a sunken portion, a depressed portion, or a step portion) which is recessed from the surface of the case 41, a “receiving portion”, a “guide receiving portion”, a “groove”, or a “groove portion”. In other words, the third end 5c includes a first portion and a pair of second portions (e.g., projections) that protrude from both sides of the first portion, and the second recess 52 is provided at the third end 5c.

The second recess 52 is a groove that extends along the second guide 35. That is, the second recess 52 extends in the direction in which the battery 5 is attached. The second recess 52 extends to the first end 5a of the battery 5 and is opened at the first end 5a. That is, the front side of the second recess 52 is opened. In this way, the second guide 35 is inserted into the second recess 52.

The second guide 35 is fitted to the second recess 52 and the third end 5c of the battery 5 slides while being guided by the second guide 35. A gap (e.g., allowance) for sliding is formed between the second guide 35 and the second recess 52. In this way, the battery 5 is smoothly guided by the second guide 35.

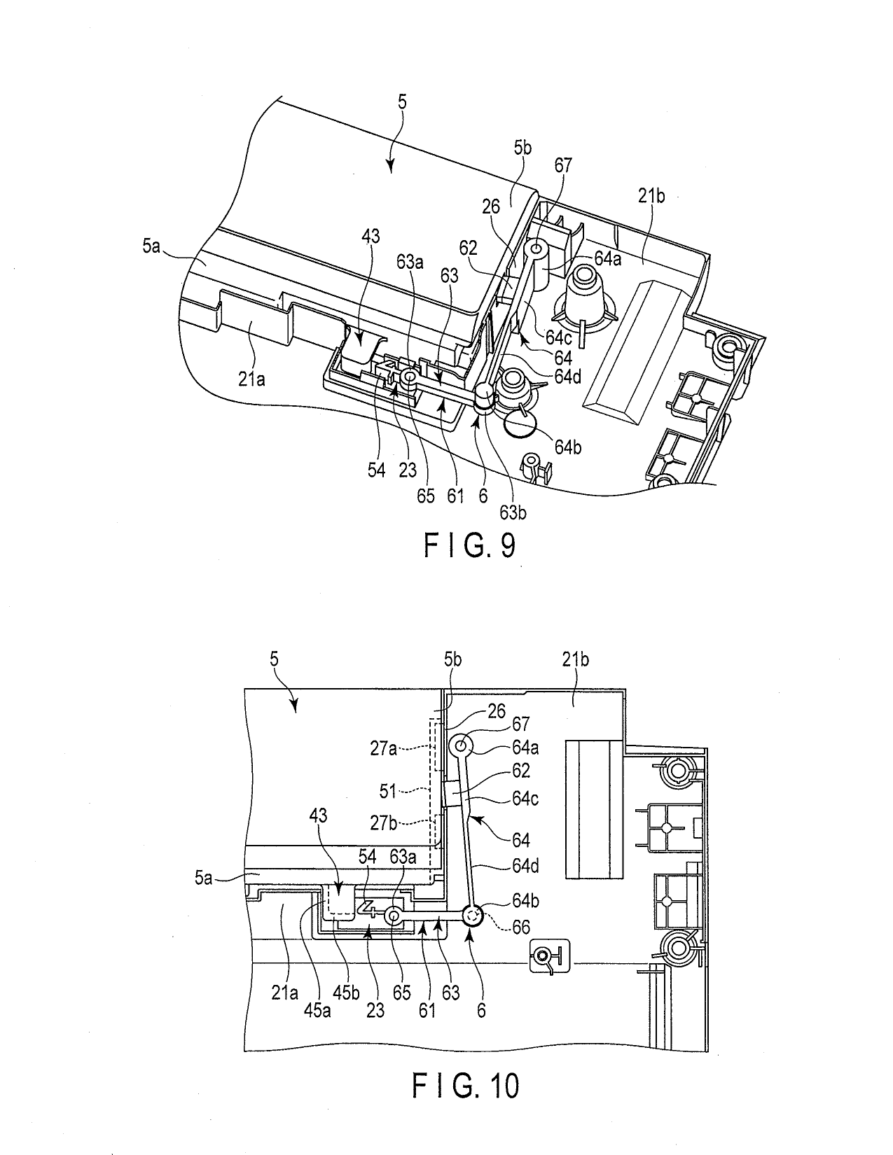

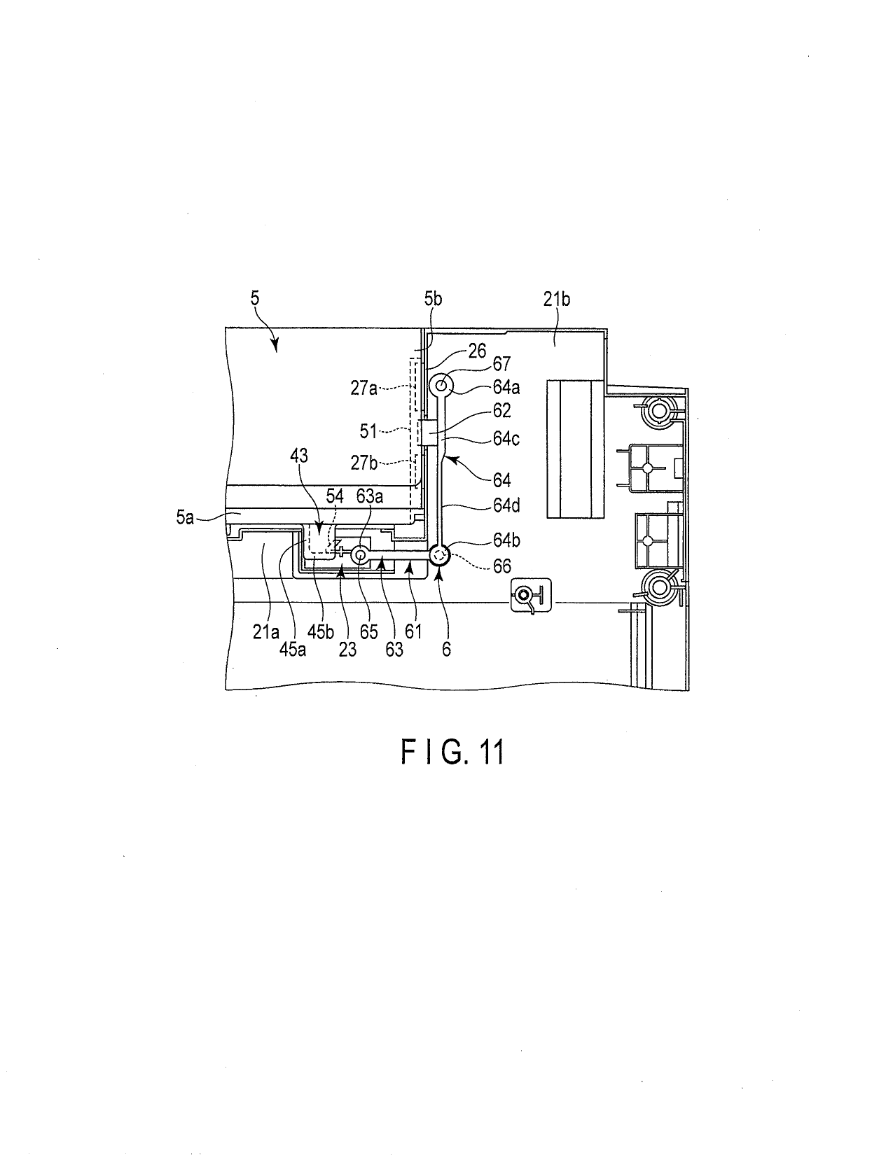

As illustrated in FIGS. 9 to 11, the first lock 23 is provided at a position corresponding to the first engaging portion 43 of the battery 5. The first lock 23 can slide between a first position (e.g., a release position; see FIG. 10) where it is disengaged from the first engaging portion 43 (release of connection, coupling, fixation, or hooking) and a second position (e.g., lock position; see FIG. 11) where it is engaged with the first engaging portion 43.

Specifically, the first lock 23 includes a protruding portion 54 (e.g., a locking piece or a rib) that is inserted into the first engaging portion 43. At the first position, the first lock 23 is separated from the first engaging portion 43. That is, the protruding portion 54 is disposed outside the first engaging portion 43. Therefore, the battery 5 can be freely removed from the housing 4.

At the second position, the first lock 23 is moved toward the first engaging portion 43 and the protruding portion 54 is inserted into the first engaging portion 43. That is, the protruding portion 54 is inserted into the gap between the case 41 and the second portion 45b of the first engaging portion 43. The rear side of the protruding portion 54 faces the second portion 45b of the first engaging portion 43. Therefore, the battery 5 is not freely removed from the housing 4.

The first lock 23 is moved in a direction along the first end 5a of the battery 5 between the first position and the second position. That is, the first lock 23 is moved in a direction (e.g., a direction substantially perpendicular to) crossing the second end 5b of the battery 5.

As illustrated in FIG. 6, the first lock 23 includes an operation portion 55 (e.g., a button or a slide button) that is exposed to the outside of the housing 4. The user moves (e.g., slides) the operation portion 55 to change the position of the first lock 23 between the first position and the second position.

The housing 4 includes a holding portion (e.g., a slope or a step portion) that holds the first lock 23 at the first position and the second position. Therefore, the first lock 23 moved to the second position (e.g., lock position) is held at the second position if the user does not intentionally perform operation.

As illustrated in FIGS. 9 to 11, the housing 4 includes a first pressing portion 6. The first pressing portion 6 includes a first link 61 and a first support 62. The first link 61 is provided in the housing 4. The first link 61 is connected to the first lock 23 and is moved in operative association with the first lock 23. The first link 61 is an example of a “connection portion”, a “joint”, an “interlocking portion”, a “portion”, a “region”, a “member”, a “part”, or a “region”.

In this embodiment, the first link 61 includes a first member 63 and a second member 64. The first member 63 is attached to the first lock 23 and extends along the first end 5a of the battery 5. The first member 63 includes a first end 63a and a second end 63b. The first end 63a is connected to (e.g., coupled or fixed) to the first lock 23. In this way, the first member 63 slides with the movement of the first lock 23.

Specifically, a first shaft 65 that extends in the thickness direction of the housing 4 is provided in the first lock 23. A hole is provided at the first end 63a of the first member 63, and the first end 63a of the first member 63 is rotatably supported by the first shaft 65 of the first lock 23. The second end 63b of the first member 63 extends to a position that deviates from a region in front of the battery 5. A second shaft 66 that extends in the thickness direction of the housing 4 is provided at the second end 63b.

A third shaft 67 that extends in the thickness direction of the housing 4 is provided on the side of the second end 5b of the battery 5. The third shaft 67 is fixed to the housing 4. The second member 64 is provided on the side of the second end 5b of the battery 5 and faces the second end 5b of the battery 5. The second member 64 includes a first end 64a and a second end 64b.

A hole is provided at the first end 64a of the second member 64, and the first end 64a of the second member 64 is rotatably supported by the third shaft 67 of the housing 4. That is, the first end 64a of the second member 64 is rotatably supported by the housing 4. A hole is provided at the second end 64b of the second member 64, and the second end 64b of the second member 64 is rotatably supported by the second shaft 66.

In this way, when the first lock 23 is moved, the first member 63 slides with the movement of the first lock 23. The second member 64 swings like a pendulum in the left-right direction. That is, the second end 64b swings on the first end 64a supported by the third shaft 67 in the left-right direction. In other words, the second member 64 can move between the first position and the second position where the second member 64 is closer to the second end 5b of the battery 5 than that at the first position.

As illustrated in FIGS. 9 to 11, the first support 62 is provided in the second member 64. The first support 62 is provided on the side of the second end 5b of the battery 5 and faces the first recess 51. The first support 62 can be moved toward the first recess 51 when the first lock 23 is closed by the first link 61. That is, when the first lock 23 is moved from the first position to the second position, the first support 62 is moved toward the first recess 51 and is then fitted to (e.g., contacts or comes into contact with) the first recess 51.

As illustrated in FIG. 6, an opening 68 is provided between the first portion 27a and the second portion 27b of the first guide 27 on the first housing 4. The leading end of the first support 62 protrudes toward the outside of the housing 4 through the opening 68. The first support 62 is disposed between the first portion 27a and the second portion 27b of the first guide 27. The first support 62 is provided in parallel to the first guide 27 in a direction in which the first guide 27 extends. In this way, the leading end of the first support 62 and the first guide 27 are inserted into the first recess 51 of the battery 5.

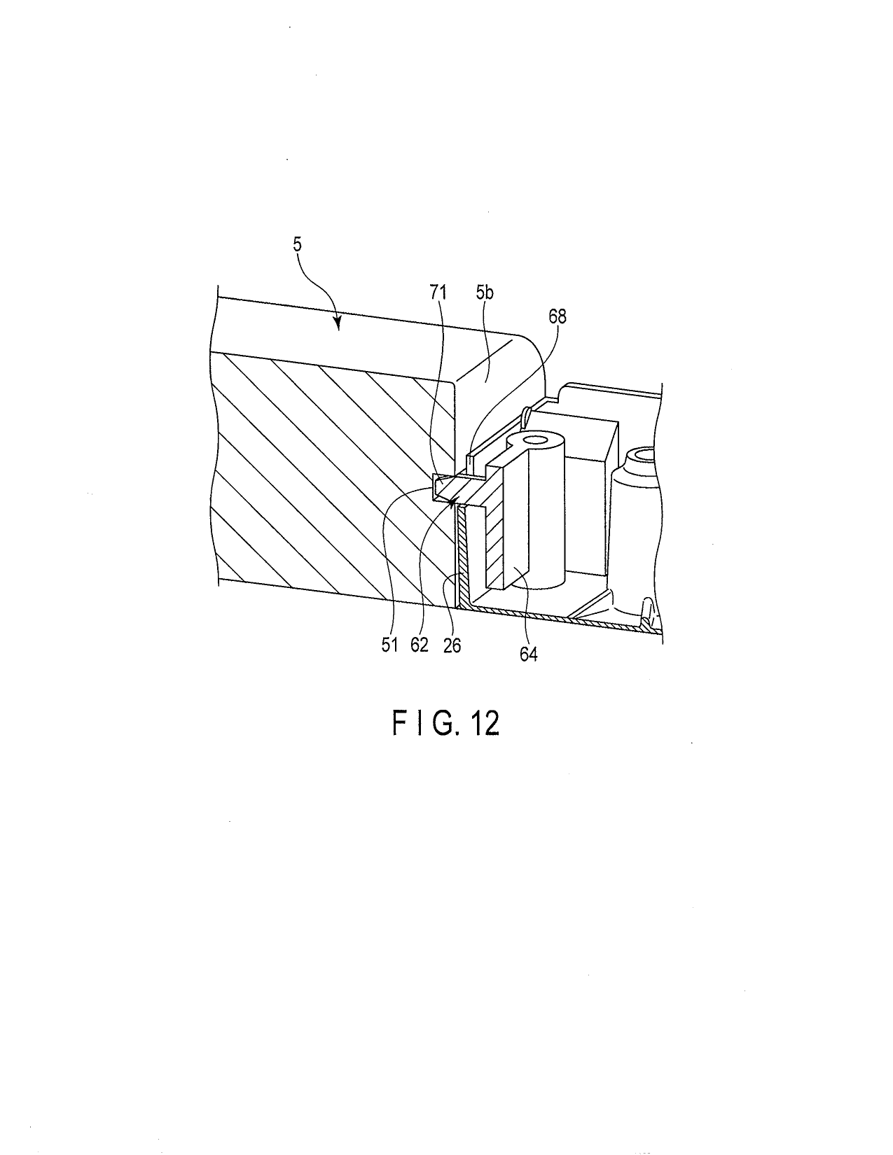

As illustrated in FIGS. 12 to 16, the first support 62 includes a wedge 71 (i.e., a wedge-shaped part, a wedge-shaped region, or an inclined portion). The wedge 71 is an example of a “pressing portion”, an “insertion portion”, an “engaging portion”, a “region”, “a region with a different thickness”, a “portion”, or a “portion with a different thickness”. The wedge 71 includes a base end 71a (e.g., first end) that is fixed to the second member 64 and a leading end 71b (e.g., second end) that is opposite to the base end 71a and protrudes toward the first recess 51.

The thickness of the wedge 71 increases from the leading end 71b to the base end 71a. In this embodiment, the wedge 71 includes two inclined surfaces 72a and 72b (e.g., inclined planes, surfaces, supporting surfaces, or faces). That is, the wedge 71 is interposed between two surfaces that extend so as not to be parallel to each other. The two inclined surfaces 72a and 72b are separated from each other in the thickness direction of the housing 4. The two inclined surfaces 72a and 72b are inclined such that the distance between the inclined surfaces 72a and 72b increases from the leading end 71b to the base end 71a.

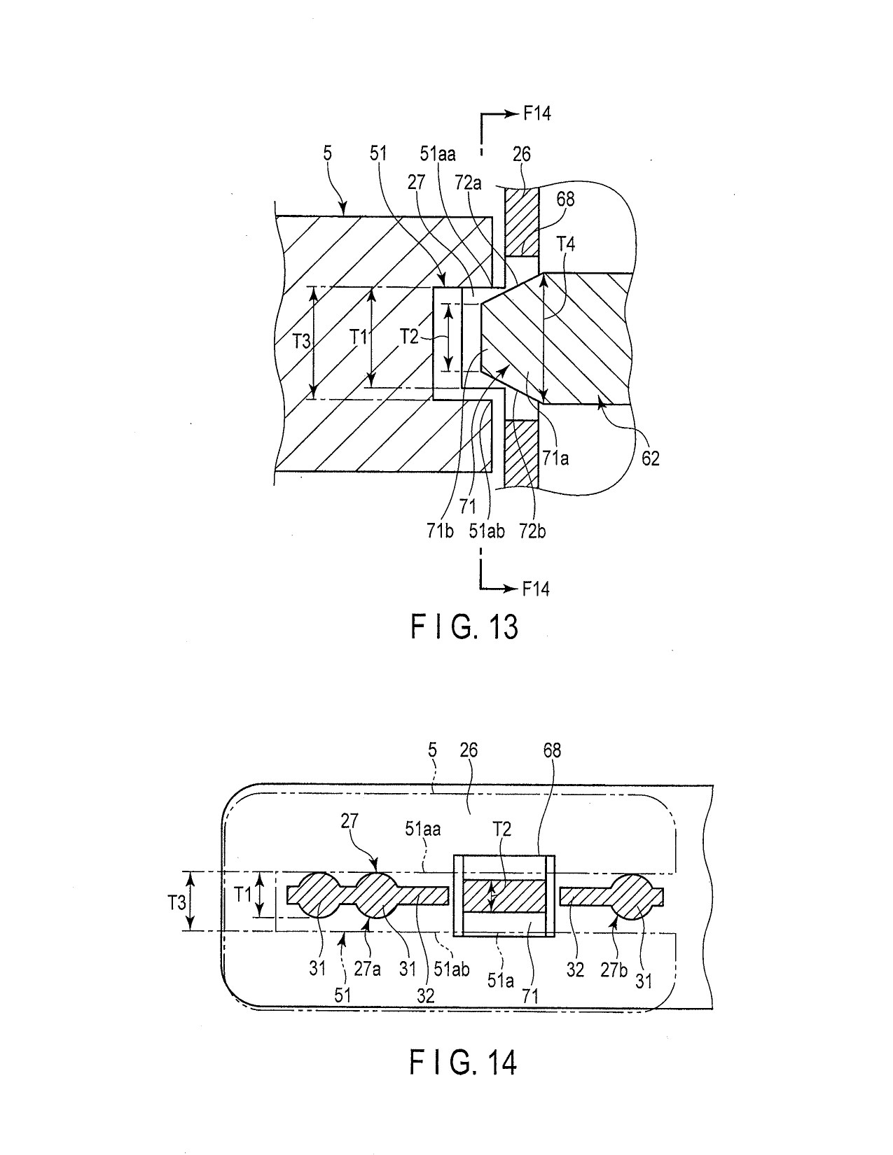

As illustrated in FIGS. 13 to 16, the thickness T2 of the leading end 71b of the wedge 71 is less than the thickness T1 (e.g., maximum thickness) of the first guide 27. In addition, the thickness T2 of the leading end 71b of the wedge 71 is less than the thickness T3 of the first recess 51. Therefore, when the wedge 71 is moved toward the first recess 51, the leading end 71b is inserted into the first recess 51.

The thickness T4 of the base end 71a of the wedge 71 is more than the thickness T1 (e.g., maximum thickness) of the first guide 27. In addition, the thickness T4 of the base end 71a of the wedge 71 is more than the thickness T3 of the first recess 51. Therefore, when the wedge 71 is further moved toward the first recess 51, the inclined surfaces 72a and 72b (i.e., the first inclined surface 72a and the second inclined surface 72b) of the wedge 71 comes into contact with (i.e., contacts or is supported by) the opening edge 51a (i.e., edge) of the first recess 51.

That is, the opening edge 51a includes a first edge 51aa which is the upper end of the first recess 51 and a second edge 51ab which is the lower end of the first recess 51. The first inclined surface 72a of the wedge 71 comes into contact with the first edge 51aa. The second inclined surface 72b of the wedge 71 comes into contact with the second edge 51ab. In this state, in practice, there is no gap (e.g., allowance) for sliding between the wedge 71 and the first recess 51. In this way, the first support 62 supports the second end 5b of the battery 5. The second end 5b of the battery 5 is supported by the first support 62 and the position thereof is fixed.

Specifically, as illustrated in FIGS. 13 and 14, in a state in which the first support 62 is retracted, the first recess 51 is supported by the first guide 27. A gap (e.g., allowance) for ensuring sooth sliding is provided between the first guide 27 and the first recess 51. That is, the first recess 51 is slightly larger than the first guide 27. Therefore, the upper end of the first recess 51 is brought into contact with the first guide 27 by the weight of the battery 5 and there is a gap between the lower end of the first recess 51 and the first guide 27.

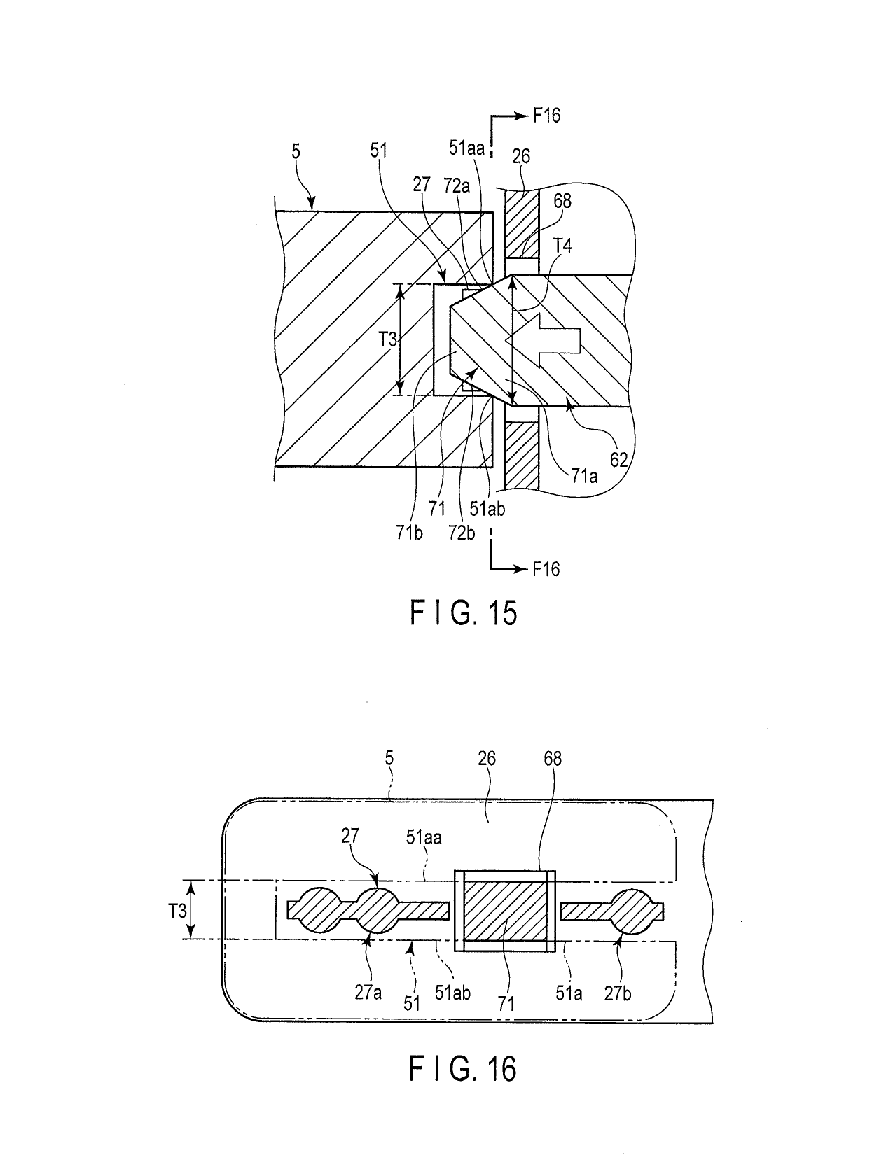

As illustrated in FIGS. 15 and 16, in the state in which the first support 62 is pressed, the first support 62 is fitted to the first recess 51. The upper end of the first recess 51 is lifted by the first inclined surface 72a. In this way, the height position of the battery 5 is determined at a position where the upper and lower ends of the first recess 51 come into contact with the first and second inclined surfaces 72a and 72b of the first support 62, respectively. The forward movement of the first support 62 is stopped in a state in which the first and second inclined surfaces 72a and 72b come into contact with the first edge 51aa and the second edge 51ab of the first recess 51, respectively.

As illustrated in FIGS. 9 to 11, the second member 64 of the first link 61 includes a first portion 64c and a second portion 64d. For example, the first portion 64c is provided between the first end 64a and the center of the second member 64. For example, the second portion 64d is provided between the second end 64b and the center of the second member 64.

The second portion 64d is thinner than the first portion 64c. The second member 64 is made of plastic or a metal material. The second portion 64d is more likely to be elastically deformed than the first portion 64c. The second portion 64d is an example of an “elastic portion”. The “elastic portion” is not limited to the above-mentioned example, but may be, for example, a spring or rubber. In other words, the first portion 64c is thicker and more rigid than the second portion 64d. The first support 62 is provided in the first portion 64c in which rigidity is ensured.

When the first lock 23 is moved from the first position toward the second position, the first support 62 is fitted to the first recess 51 and is not moved any further before the first lock 23 reaches the second position. When the first lock 23 is moved to the second position in a state in which the first support 62 is fitted to the first recess 51, the second portion 64d of the second member 64 between the first lock 23 and the first support 62 is elastically deformed.

The first lock 23 reaching the second position is held at the second position by a holding structure provided in the housing 4. In this case, the first support 62 is pressed toward the first recess 51 by the elastically deformed second portion 64d of the second member 64. In this way, the reliable contact of the first support 62 with the second end 5b of the battery 5 is achieved. And the rattling of the battery 5 is prevented.

Similarly, as illustrated in FIGS. 17 and 18, the second lock 24 and a second pressing portion 7 are provided in the housing 4. Components having the same or similar functions as those of the first pressing portion 6 are denoted by the same reference numerals and the description thereof will not be repeated. Structures other than the following structures are the same as those of the first pressing portion 6.

The second lock 24 is provided at a position corresponding to the second engaging portion 44 of the battery 5. The second lock 24 can slide between a first position (e.g., a release position; see FIG. 17) where it is disengaged from the second engaging portion 44 (e.g., release of connection, coupling, fixation, or hooking) and a second position (e.g., lock position; see FIG. 18) where it is engaged with the second engaging portion 44.

The second lock 24 is moved in a direction along the first end 5a of the battery 5 between the first position and the second position. That is, the second lock 24 is moved in a direction (e.g., a direction substantially perpendicular to) crossing the third end 5c of the battery 5.

As illustrated in FIGS. 17 and 18, the second pressing portion 7 includes a second link 81 and a second support 82. The second link 81 is provided in the housing 4. The second link 81 is connected to the second lock 24 and is moved in operative association with the second lock 24. The second link 81 is an example of a “joint”, a “connection portion”, a “link”, a “portion”, a “region”, a “member”, a “part”, or a “region”.

In this way, when the second lock 24 is moved, the first member 63 is moved with the movement of the second lock 24. The second member 64 swings like a pendulum in the left-right direction. That is, the second end 64b swings on the first end 64a supported by the third shaft 67 in the left-right direction. In other words, the second member 64 can be moved between the first position and the second position where the second member 64 is closer to the third end 5c of the battery 5 than that at the first position.

A second support 82 is provided in the second member 64. The second support 82 is provided on the side of the third end 5c of the battery 5 and faces the second recess 52. The second support 82 can be moved toward the second recess 52 when the second lock 24 is closed by the second link 81. That is, when the second lock 24 is moved from the first position to the second position, the second support 82 is moved toward the second recess 52 and is fitted to the second recess 52. The second support 82 may be operatively associated with the first lock 23 or other members, not the second lock 24.

Similarly to the first support 62, the second support 82 includes a wedge 71. The wedge 71 includes a leading end 71b that is inserted into the second recess 52 and comes into contact with the opening edge 52a of the second recess 52. The second support 82 supports the third end 5c of the battery 5. The third end 5c of the battery 5 is supported by the second support 82 and the position thereof is fixed.

As illustrated in FIG. 5, the first support 62 and the second support 82 are separately disposed on both sides of the battery 5 and face each other. The battery 5 is interposed between the first support 62 and the second support 82 and is supported between the first support 62 and the second support 82.

According to this structure, it is possible to suppress the rattling of the electronic apparatus 10.

In this embodiment, the battery 5 slides and is attached to the housing 4 from the rear side. In this case, a gap (e.g., allowance) for smooth sliding is provided between the battery 5 and the housing 4. In addition, a gap is formed between the battery 5 and the housing 4 due to component tolerance. The gap may cause the rattling of the battery attached to the housing 4.

In this embodiment, the electronic apparatus 10 includes the battery 5 including the recess 51 and the support 62 that can be moved to the recess 51. The support 62 includes the wedge 71 which includes the leading end 71a inserted into the recess 51 and comes into contact with the opening edge 51a of the recess 51. According to this structure, the battery 5 can be supported by the wedge 71 which comes into contact with the opening edge 51a of the recess 51. Therefore, it is possible to reduce or prevent the rattling of the battery 5.

In this embodiment, the electronic apparatus includes the first lock 23 which is provided in the housing 4 and is engaged with the battery 5 and the link 61 which is operatively associated with the first lock 23. The support 62 is moved to the battery 5 when the first lock 23 is closed by the link 61 and comes into contact with the battery 5. According to this structure, the movement of the support 62 and the support of the battery 5 are simultaneously achieved only by the operation of the first lock 23 preventing the detachment of the battery 5. Therefore, the user does not need to perform a special operation for moving the support 62. Therefore, it is possible to improve the use convenience of the electronic apparatus 10.

In this embodiment, the first engaging portion 43 and the second engaging portion 44 are provided at the first end 5a (e.g., front end) of the battery 5. Therefore, only the first engaging portion 43 and the second engaging portion 44 are not sufficient to prevent rattling at the fourth end 5d (e.g., rear end) of the battery 5. That is, rattling occurs in the thickness direction of the battery 5 or the twist direction of the battery 5.

In this embodiment, the battery 5 includes the first end 5a at which the first engaging portion 43 fitted to the first lock 23 is provided and the second end 5b at which the first recess 51 extending in a direction intersecting the first end 5a is provided. The first support 62 is fitted to the first recess 51 to support the second end 5b (e.g., the side end) of the battery 5. That is, the end of the battery 5 other than the front end is supported. In this way, it is possible to reduce or prevent rattling in the thickness direction of the battery 5 or the twist direction of the battery 5. Therefore, it is possible to further improve product quality.

In this embodiment, the housing 4 includes the first guide 27 which guides the battery 5. The first recess 51 is a groove into which the first guide 27 is inserted. In this way, the first support 62 supports the battery 5 using the groove into which the first guide 27 is inserted. That is, it is not necessary to provide a special structure for receiving the first support 62 in the battery 5. Therefore, it is possible to reduce the manufacturing costs of the electronic apparatus 10.

In this embodiment, the first guide 27 includes the first portion 27a and the second portion 27b which are separated from each other. The first support 62 is disposed between the first portion 27a and the second portion 27b of the guide 27. In this way, the first recess 51 guided by the guide 27 reliably faces the first support 62. According to this structure, it is possible to further reduce the rattling of the electronic apparatus 10.

In this embodiment, the housing 4 includes the opening 68 provided between the first portion 27a and the second portion 27b of the guide 27. The leading end 71b of the first support 62 protrudes to the outside of the housing 4 through the opening 68. In this way, the link 61 can be provided in the housing 4. Therefore, it is possible to improve the outward appearance of the electronic apparatus 10.

In this embodiment, the link 61 includes the elastic portion. The first support 62 is pressed toward the first recess 51 by the elastic portion 64d. In this way, the first support 62 is reliably fitted to the first recess 51. According to this structure, it is possible to further reduce the rattling of the electronic apparatus 10. When the link 61 includes the elastic portion 64d, it is possible to reliably support the battery 5 even when the battery 5 has component tolerance.

In this embodiment, the battery 5 includes the third end 5c at which the second recess 52 is provided. The second support 82 can be moved toward the second recess 52 to support the third end 5c of the battery 5. In this way, the second support 82 can support the end of the battery 5 other than the end supported by the first support 62. According to this structure, it is possible to further reduce the rattling of the electronic apparatus 10.

When the first support 62 and the second support 82 are separately provided on both sides of the battery 5, both sides of the battery 5 are supported by the first support 62 and the second support 82. Therefore, the battery 5 is less likely to lean to one side from the center of the accommodating portion 21 in the lateral direction. According to this structure, it is possible to further improve product quality and a load is less likely to be applied between the first connector 22 and the second connector 42.

### Third Embodiment

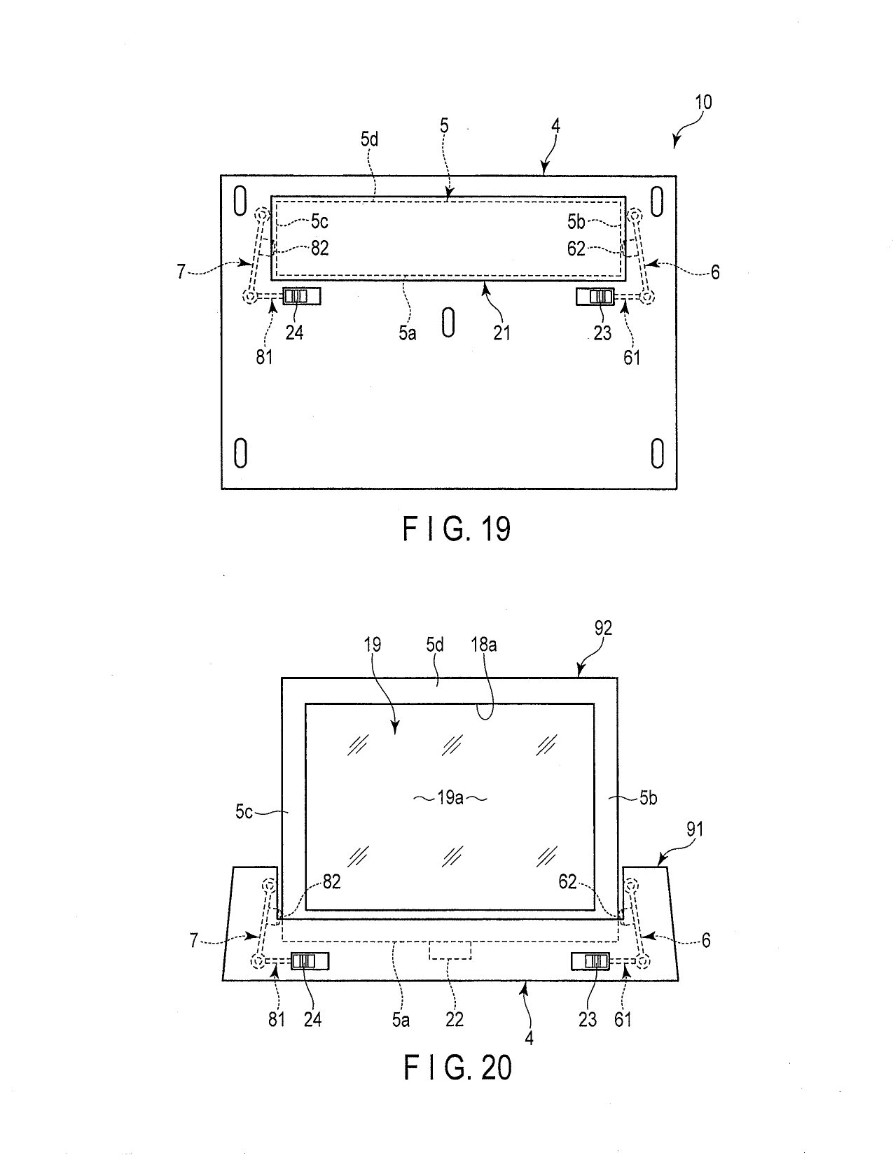

Next, an electronic apparatus 10 according to a third embodiment will be described with reference to FIG. 19. In the third embodiment, components having the same or similar functions as those in the second embodiment are denoted by the same reference numerals and the description thereof will not be repeated. In addition, structures other than the following structures are the same as those in the second embodiment.

As illustrated in FIG. 19, an accommodating portion 21 in which a battery 5 is accommodated is provided in a lower wall 15b of the electronic apparatus 10. In this embodiment, the bottom of the accommodating portion 21 is opened. The battery 5 is attached to the accommodating portion 21 in the thickness direction of the housing 4. A first pressing portion 6 and a second pressing portion 7 are provided on both sides of the battery 5.

In this structure, similarly to the second embodiment, it is possible to suppress the rattling of the electronic apparatus 10.

### Fourth Embodiment

Next, an electronic apparatus 10 according to a fourth embodiment will be described with reference to FIG. 20. In the fourth embodiment, components having the same or similar functions as those in the second embodiment are denoted by the same reference numerals and the description thereof will not be repeated. In addition, structures other than the following structures are the same as those in the second embodiment.

FIG. 20 illustrates an external connection device 91 according to this embodiment. The external connection device 91 is an example of an “electronic apparatus”. The external connection device 91 is called, for example, an “expansion device”, a “cradle”, a “dock”, a “docking station”, a “holder”, a “holding device”, or a “supporting device”.

An external device 92 is detachably attached to the external connection device 91. The external device 92 is, for example, a mobile phone (including a smart phone), a tablet terminal (slate PC), a notebook PC, or a portable television, but is not limited thereto. The external device 92 is an example of a “module” or a “unit”.

According to this structure, similarly to the second embodiment, it is possible to suppress the rattling of the electronic apparatus 10.

### Fifth Embodiment

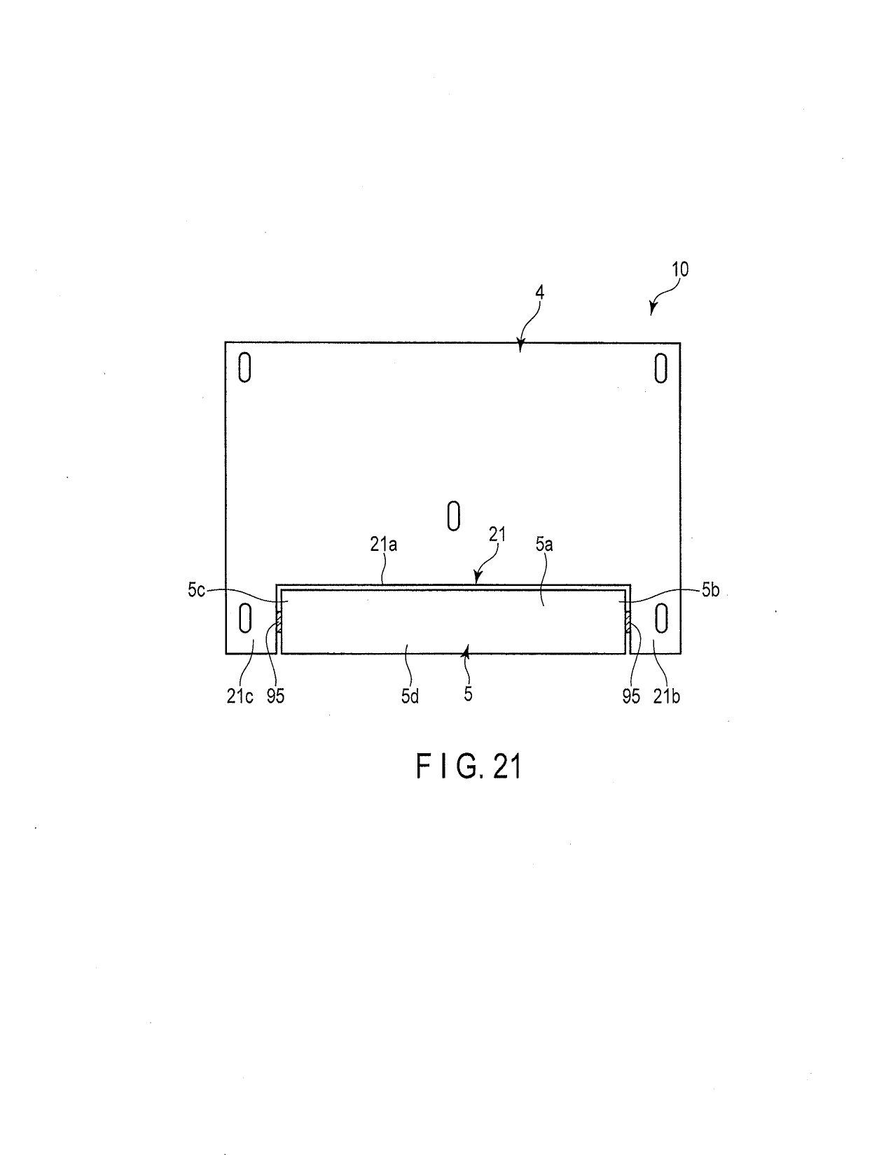

Next, an electronic apparatus 10 according to a fifth embodiment will be described with reference to FIG. 21. In the fifth embodiment, components having the same or similar functions as those in the second embodiment are denoted by the same reference numerals and the description thereof will not be repeated. In addition, the structures other than the following structures are the same as those in the second embodiment.

As illustrated in FIG. 21, the electronic apparatus 10 includes a housing 4 and a battery 5 (i.e., a module or a unit). An elastic member 95 is provided between the housing 4 and the battery 5. An example of the elastic member 95 is a sponge member. The elastic member 95 is interposed between the housing 4 and the battery 5 and applies reaction force to the battery 5. The battery 5 is supported by the elastic member 95. The elastic member 95 supports, for example, a second end 5b and a third end 5c of the battery 5.

According to this structure, similarly to the second embodiment, it is possible to suppress the rattling of the electronic apparatus 10.

According to the structures of the first to fifth embodiments, it is possible to suppress the rattling of the electronic apparatus 10. The embodiments are not limited to the above-described embodiments, but the components according to the above-described embodiments may be changed without departing from the scope and spirit of the invention. In addition, a plurality of components according to the above-described embodiments may be appropriately combined with each other to form various structures. For example, some of the components according to the above-described embodiments may be removed. Components according to different embodiments may be appropriately combined with each other.

For example, the embodiments are not limited to the structure in which the first and second supports 62 and 82 are operatively associated with the first and second locks 23 and 24. The first and second supports 62 and 82 may be moved independently from the first and second locks 23 and 24. In the above-described embodiments, each of the first and second supports 62 and 82 includes the wedge 71. However, the shape of the first and second support 62 and 82 is not limited thereto. A module (i.e., unit) may not include the first and second recesses 51 and 52. The first and second supports 62 and 82 may come into contact with a planar region (i.e., a planar portion or a wall portion) of the module (i.e., unit). In this structure, it is also possible to reduce the rattling of the module. In addition, the module may include a recess and the support may include a wedge-shaped portion. In this case, it is possible to further reduce the rattling of the module.

The first and second supports 62 and 82 may be provided in a region other than the region in which the first and second guides 27 and 35 are provided. The first and second recesses 51 and 52 are not limited to the guide grooves, but may be recessed portions which are provided to receive the first or second supports 62 or 82 or for other purposes. In addition, each of the supports 62 and 82 may form a portion of or the entire first or second guide 27 or 35. That is, the entire first or second guide 27 or 35 may protrude.

The number of supports 62 and 82 is not limited to two, but only one of the supports 62 and 82 may be provided. The first or second lock 23 or 24 and the first member 63 of the first or second link 61 or 81 may be integrated with each other. In this case, it is possible to reduce the number of components. In addition, an elastic member, such as sponge, may be attached to the leading end of each of the first and second supports 62 and 82. In this case, it is possible to reduce the sound during fitting and reliably fit the components.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A television comprising:
a housing comprising a first connector and a lock;
a battery comprising a first end and a second end, wherein the battery is configured to attach to the housing,
wherein the first end comprises a second connector configured to connect to the first connector and an engaging portion configured to engage the lock, and
the second end extends in a direction crossing the first end and comprises a first recess;
a link associated with the lock; and
a first support configured to be moved to the first recess by the link, wherein the first support comprises a wedge configured to contact with an opening edge of the first recess with an end of the wedge in the first recess, and wherein the first support is configured to support the second end of the battery when the lock is locked.

2. The television of claim 1,
wherein the first recess comprises a groove,
the housing comprises a guide configured to be in the groove and to guide the battery, and
the end of the first support is configured to be in the groove.

3. The television of claim 2,
wherein the guide comprises a first portion and a second portion, wherein the second portion is separate from the first portion, and
wherein the first support is between the first portion and the second portion of the guide.

4. The television of claim 3,
wherein the housing comprises an opening between the first portion and the second portion of the guide,
wherein the link is in the housing, and
wherein the end of the first support is configured to protrude toward an outside of the housing through the opening.

5. The television of claim 1,
wherein the link comprises an elastic portion, and
wherein the first support is configured to be pressed toward the first recess by the elastic portion.

6. The television of claim 1, further comprising:
a second support,
wherein the battery comprises a third end opposite the second end, the third end comprising a second recess, and
wherein the second support is configured to be moved to the second recess, wherein the second support comprises a wedge configured to contact with an opening edge of the second recess with an end of the wedge in the second recess, and wherein the second support is configured to support the third end of the battery.

7. The television of claim 6,
wherein the battery is configured to be between the first support and the second support.

8. The television of claim 1,
wherein the link comprises a first member and a second member, wherein the first member is configured to attach to the lock, and wherein the second member comprises the first support, a first end configured to be rotatably supported by the housing, and a second end configured to connect to the first member.

9. An electronic apparatus comprising:
a housing; and
a module comprising a recess, wherein the module is configured to attach to the housing;
wherein the housing comprises a support configured to be moved to the recess, and wherein the support comprises a wedge configured to contact an opening edge of the recess with an end of the wedge in the recess.

10. An electronic apparatus comprising:
a housing comprising a lock;
a module configured to attach to the housing and to engage the lock;
a link configured to associate with the lock; and
a support configured to be moved to the module by the link and to contact the module when the lock is locked.
